(19) United States
(12) Patent Application Publication
(10) Pub. No.: US 2014/0057417 A1
(43) Pub. Date: Feb. 27, 2014

(54) Method for Producing an Optoelectronic Semiconductor Chip

(71) Applicants: Christian Leirer, Regensburg (DE); Anton Vogl, Sinzing (DE); Andreas Biebersdorf, Regensburg (DE); Joachim Hertkorn, Alteglofsheim (DE); Tetsuya Taki, Tokyo (JP); Rainer Butendeich, Regensburg (DE)

(72) Inventors: Christian Leirer, Regensburg (DE); Anton Vogl, Sinzing (DE); Andreas Biebersdorf, Regensburg (DE); Joachim Hertkorn, Alteglofsheim (DE); Tetsuya Taki, Tokyo (JP); Rainer Butendeich, Regensburg (DE)

(73) Assignee: OSRAM OPTO SEMICONDUCTORS GMBH, Regensburg (DE)

(21) Appl. No.: 14/002,968

(22) PCT Filed: Feb. 15, 2012
(86) PCT No.: PCT/EP2012/052617

§ 371 Date: Nov. 8, 2013

(30) Foreign Application Priority Data
Mar. 3, 2011 (DE) 10 2011 012 925.1

(51) Int. Cl. H01L 21/02; H01L 33/00; H01L 31/18

(52) U.S. Cl. CPC H01L 21/02513; H01L 21/0254; H01L 31/1856; H01L 33/0075
USPC 438/478

(57) ABSTRACT

A method for producing an optoelectronic semiconductor chip is disclosed. A growth substrate is provided in an epitaxy installation. At least one intermediate layer is deposited by epitaxy on the growth substrate. A structured surface that faces away from the growth substrate is produced on the side of the intermediate layer facing away from the growth substrate. An active layer is deposited by epitaxy on the structured surface. The structured surface is produced in the epitaxy installation and the active layer follows the structuring of the structured surface at least in some regions in a conformal manner or at least in some sections essentially in a conformal manner.

This patent application is a national phase filing under section 371 of PCT/EP2012/052617, filed Feb. 15, 2012, which claims the priority of German patent application 10 2011 012 925.1, filed Mar. 3, 2011, each of which is incorporated herein by reference in its entirety.

### TECHNICAL FIELD

An optoelectronic semiconductor chip is specified.

### BACKGROUND

For example, in the case of light-emitting diode chips based on GaN, in particular in the case of light-emitting diode chips based on InGaN, the effect occurs that as the current densities of the current with which the light-emitting diode chip is operated increase, the light emission rises proportionally less than linearly. If the light-emitting diode chips are to be operated efficiently, they must therefore be operated with a low current density.

### SUMMARY OF THE INVENTION

Embodiments of the invention specify an optoelectronic semiconductor chip that can be operated with high efficiency at high current densities.

A method for producing an optoelectronic semiconductor chip is specified. The optoelectronic semiconductor chip can be a radiation-generating semiconductor chip such as a light-emitting diode chip, for example. Furthermore, it can be a radiation-detecting semiconductor chip such as a photodiode, for example.

In accordance with at least one embodiment of the method, firstly a growth substrate is provided in an epitaxy installation. The growth substrate is a substrate wafer on which the semiconductor material of the optoelectronic semiconductor chip to be produced can be grown epitaxially. By way of example, the growth substrate is formed with sapphire, GaN, SiC or silicon. In particular, the growth substrate can also consist of one of said materials.

The growth substrate is provided in an epitaxy installation in which the optoelectronic semiconductor chip is subsequently produced. By way of example, the epitaxy installation is an MOVPE (Metal Organic chemical Vapor Phase Epitaxy) reactor in which the optoelectronic semiconductor chip can be produced at least partly by metal organic vapor phase epitaxy.

In accordance with at least one embodiment of the method, at least one intermediate layer is epitaxially deposited onto the growth substrate. In this case, the epitaxial deposition is effected in the epitaxy installation. The at least one intermediate layer is for example a doped semiconductor layer, by way of example an n-doped semiconductor layer, which is deposited onto the growth substrate.

In accordance with at least one embodiment of the method, a structured surface is produced at that side of the intermediate layer which faces away from the growth substrate. The structured surface can be for example the surface of a structured layer which is produced on that side of the intermediate layer which faces away from the growth substrate. Furthermore, it is possible for that side of the intermediate layer which faces away from the growth substrate, that is to say the surface of the intermediate layer itself, to be altered to form a structured surface.

In the present case, a structured surface is understood to be a surface which comprises structures, such that it cannot be designated as smooth with respect to criteria that are customary in the case of MOVPE growth. The structured surface comprises depressions and elevations, for example, wherein the elevations of the structured surface are at least a few monolayers of semiconductor material higher than the depressions of the structured surface.

The average distance between two elevations in a lateral direction is, for example, at least 50 nm and/or at most 50 μm, in particular at least 500 nm and/or at most 1500 nm. The distance between a depression and an adjacent elevation in a vertical direction results accordingly with a sidewall angle of the facets of approximately 60°.

In accordance with at least one embodiment of the method, a subsequent method step involves epitaxially depositing an active layer onto the structured surface. An active layer, which is provided for generating or detecting electromagnetic radiation, for example, during the operation of the optoelectronic semiconductor chip, is epitaxially deposited onto the structured surface. In this case, it is also possible for further layers to be situated between the structured surface and the active layer, the further layers likewise being epitaxially deposited onto the structured surface. The active layer can furthermore comprise a plurality of layers, that is to say that, in particular, an active layer sequence can be involved. By way of example, the active layer comprises single or multi quantum films.

In accordance with at least one embodiment of the method, the structured surface is produced in the epitaxy installation. That is to say that the structured surface is, for example, not produced by roughening by means of etching outside the epitaxy installation or by applying mask layers to the growth substrate outside the epitaxy installation, rather the structured surface is produced in situ during the epitaxy process.

In accordance with at least one embodiment of the method, the active layer is grown in such a way that the profile thereof follows the structuring of the structured surface conformally at least in places or substantially conformally at least in places. That is to say that the active layer does not overgrow the structured surface in such a way that the structurings of the structured surface are simply covered, rather the active layer follows the profile of the structured surface at least in places or it substantially follows said profile. In this case, “substantially” means that the profile of the active layer can deviate from a strictly conformal mapping of the structured surface. However, if the structured surface comprises depressions and elevations, for example, then depressions of the active layer are situated in the region of depressions of the structured surface and elevations of the active layer are situated in the region of elevations of the structured surface. This is the case at least in sections, such that the active layer has a structuring similar to the structured surface at least in sections.

In accordance with at least one embodiment of the method for producing an optoelectronic semiconductor chip, the method comprises the following steps:
providing a growth substrate in an epitaxy installation,
epitaxially depositing at least one intermediate layer onto the growth substrate,
producing a structured surface facing away from the growth substrate at that side of the intermediate layer which faces away from the growth substrate,
epitaxially depositing an active layer onto the structured surface, wherein
the structured surface is produced in the epitaxy installation, and
the active layer follows the structuring of the structured surface conformally at least in places or substantially conformally at least in places.

In this case, the method is based on the following insight, inter alia, forming a structured active layer makes it possible to create an active layer which has an enlarged outer area and thus an enlarged emission area or an enlarged detection area in comparison with an active layer that is grown onto a planar surface in an unstructured manner. As a result of this larger area of the active layer, the efficiency of, for example, a radiation-emitting optoelectronic semiconductor chip increases with the same chip size, that is to say with the same chip cross section and the same current. Alternatively, it is possible to use chips having a reduced cross-sectional area which, on account of the enlarged area of the active layer, have an efficiency comparable to that of a chip without a structured surface. If the structures on the active surface are ideal hexagonal pyramids, for example, then the area of the active layer can be enlarged by approximately a factor of 1.4. The efficiency can thereby be increased by 10%. That is to say that the increase in the efficiency can be at least 5% or more.

In accordance with at least one embodiment of the optoelectronic semiconductor chip, the epitaxially produced layers of the semiconductor chip are at least partly or completely based on a nitride compound semiconductor material.

In the present context, based on nitride compound semiconductor material means that the semiconductor layer sequences or at least a portion thereof comprises or consists of a nitride compound semiconductor material, preferably AlₙGaₘIn₁₋ₙ₋ₘN, wherein 0≦n≦1, 0≦m≦1 and n+m≦1. In this case, said material need not necessarily have a mathematically exact composition according to the above formula. Moreover, it can comprise, for example, one or more dopants and additional constituents. For the sake of simplicity, however, the above formula includes only the essential constituents of the crystal lattice (Al, Ga, In, N), even if these can be replaced and/or supplemented in part by small amounts of further substances.

By way of example, the layers are based on an InGaN and/or a GaN semiconductor material.

In accordance with at least one embodiment of the method, the structured surface is produced by means of determined variation of the growth conditions in the epitaxy installation. That is to say that a structured surface is grown or produced by setting growth conditions such as, for example, the growth temperature or the flow rates in the epitaxy installation. A further intervention from outside, such as introducing an additional etchant, for example, is therefore not necessary. In this case, it is possible for exactly one parameter of the growth conditions to be varied or for a plurality of parameters of the growth conditions to be varied simultaneously, in order to produce the structured surface.

In accordance with at least one embodiment of the method, the structured surface is produced by means of determined variation of the temperature in the epitaxy installation. In this case, the temperature in the epitaxy installation can be increased or decreased for the purpose of producing the structured surface. As a result, by way of example, the outer area of the intermediate layer can be structured to form the structured surface or the varied temperature in the epitaxy installation is set during the growth of a structured layer onto the outer area of the intermediate layer, such that the structured surface forms at the structured layer.

In accordance with at least one embodiment of the method, the structured surface can be produced by means of determined variation of the flow rate of a precursor and/or of a flow rate of a carrier gas in the epitaxy installation. The variation of the flow rate can involve, for example, decreasing or switching off the flow of a precursor and/or of a carrier gas. At the same time, the flow rate for a different precursor and/or a different carrier gas can be increased.

In accordance with at least one embodiment of the method, for the purpose of forming the structured surface, the temperature in the epitaxy installation is reduced in such a way that so-called V-defects form. A V-defect has in the nitride compound semiconductor material, for example, the form of an open pyramid inverted in the growth direction and having a hexagonal base area, for example. This defect has the form of a V in cross section. A V-defect can be produced in the nitride compound semiconductor material, for example, in a layer which is based on GaN or consists of this semiconductor material, by setting the growth parameters, in particular the growth temperature. The size of the V-defect then depends on the thickness of the layer in which the V-defect is produced.

In accordance with at least one embodiment of the method, the intermediate layer comprises threading dislocations, wherein for the most part the V-defects respectively form at a threading dislocation. The threading dislocations arise for example during the hetero-epitaxy of the semiconductor material of the intermediate layer onto the growth substrate, which has a different lattice constant than the semiconductor material. By way of example, the intermediate layer is grown onto a growth substrate composed of sapphire, which can have a lattice mismatch of up to approximately 14% with respect to the nitride compound semiconductor material of the intermediate layer. The density of the V-defects can be set by means of the choice of the growth substrate and the growth conditions, in particular the growth temperature. The density of the V-defects is determined by the roughness of the structured surface, that is to say for example, the depth of depressions and the distance between the latter.

In accordance with at least one embodiment of the method, the intermediate layer is based on GaN, for example on n-doped GaN, and the V-defects are grown at a temperature in the epitaxy installation of less than 900° C. Such growth conditions prove to be particularly advantageous for producing V-defects.

In accordance with at least one embodiment of the method, the intermediate layer is based on GaN and, for the purpose of forming the structured surface, the flow of an NH₃ precursor is decreased or prevented for a specific time. In this case, the temperature in the epitaxy installation can simultaneously also be decreased. After the conclusion of the growth of the intermediate layer, before the growth of the active layer, a decomposition of the GaN-based surface of the intermediate layer which is situated facing away from the growth substrate can occur on account of the reduced or absent nitrogen component. This leads to a roughening of said surface and thus to the formation of the structured surface.

In accordance with at least one embodiment of the method, a masking layer comprising a plurality of openings toward the intermediate layer is applied to that surface of the intermediate layer which faces away from the growth substrate, and the structured surface is formed by epitaxial overgrowth of the masking layer. That is to say, that there is applied to the epitaxially produced intermediate layer a layer based on silicon nitride, for example, which can be structured, for example, photolithographically in such a way that it comprises openings in which the intermediate layer can be at least partly exposed. During the subsequent overgrowth of this masking layer, in particular for GaN-based semiconductor materials, hexagonal pyramid structures or trapezoidal structures can then form. In this way, therefore, a structured layer is produced which comprises the structured surface at its side facing away from the growth substrate.

In accordance with at least one embodiment of the method, during the epitaxial overgrowth of the masking layer, material is introduced into the openings of the masking layer, such that the epitaxially grown material is partly in direct contact with the intermediate layer.

### BRIEF DESCRIPTION OF THE DRAWINGS

The methods described here are explained in greater detail below on the basis of exemplary embodiments and the associated Figures.

FIGS. 1, 2 and 3 show, on the basis of schematic sectional illustrations, optoelectronic semiconductor chips produced by different embodiments of the methods described here.

Elements that are identical, of identical type or act identically are provided with the same reference signs in the figures. The figures and the size relationships of the elements illustrated in the figures among one another should not be regarded as to scale. Rather, individual elements may be illustrated with an exaggerated size in order to enable better illustration and/or in order to afford a better understanding.

### DETAILED DESCRIPTION OF ILLUSTRATIVE EMBODIMENTS

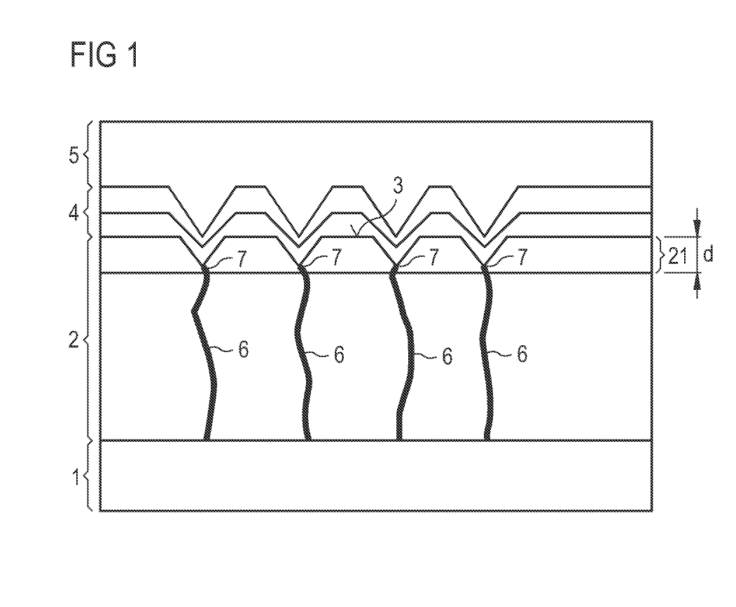

The schematic sectional illustration in FIG. 1 shows an optoelectronic semiconductor chip, for example, a light-emitting diode chip. The optoelectronic semiconductor chip comprises a growth substrate 1. The growth substrate 1 can be a sapphire substrate, for example. An intermediate layer 2 is applied to the growth substrate 1. The intermediate layer 2 is formed with n-doped GaN, for example. On account of the lattice difference between growth substrate 1 and intermediate layer 2, threading dislocations 6 form in the intermediate layer 2, said threading dislocations extending through the intermediate layer 2.

With variation of the growth conditions, the structured layer 21 is epitaxially grown onto that side of the intermediate layer 2, which faces away from the growth substrate 1. In this case, the epitaxial growth is effected in the same epitaxy installation as the production of the intermediate layer 2. By way of example, the structured layer 21 is grown at a temperature in the epitaxy installation of <900° C. V-defects 7 of regular size which respectively form at threading dislocations 6 arise in this way. The density of the V-defects 7 can be, for example, at least 5×10⁷/cm̂2, for example at least 10⁸/cm̂2. The V-defects are grown with a size such that they almost touch one another. This can be set, for example, by means of the thickness d of the structured layer 21. In this case, the thickness d depends on the density of the V-defects, which can be set by means of the choice of temperature.

The V-defects 7 produce a structured surface 3 comprising depressions in the region of the V-defects 7. Elevations are arranged between the depressions, which elevations can have the form of hexagonal pyramids, for example.

The growth conditions are subsequently varied. That is to say that the subsequent active layer 4, which can consist of a plurality of layers in the present case, is grown with different materials and/or different temperatures.

In terms of its structuring, the active layer 4 produced in this way follows the structuring of the structured surface 3 as conformally as possible. This therefore gives rise to an undulatory active layer having a larger outer area than an active layer grown, for example, directly onto the outer area of a smooth or planar intermediate layer 2. This results in the increase in efficiency described above.

Finally, a covering layer 5 can be grown, which is formed with a p-conducting semiconductor material, for example, which can be based on GaN.

In further method steps, by way of example, the growth substrate 1 can be detached and corresponding metallic contacts for making contact with the optoelectronic semiconductor chip can be produced.

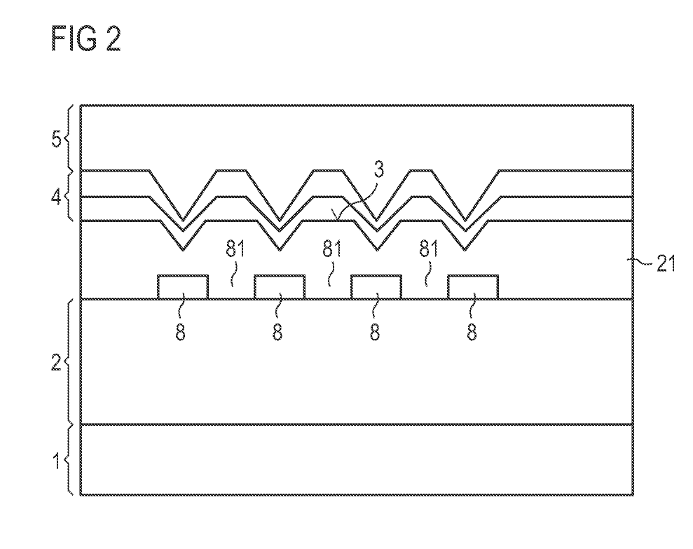

In conjunction with FIG. 2, a further exemplary embodiment of a method described here is explained in greater detail on the basis of the optoelectronic semiconductor chip produced thereby. In contrast to the optoelectronic semiconductor chip in FIG. 1, no V-defects are formed in this embodiment of the method. That is to say that the growth temperature, in other words the temperature in the epitaxy installation, does not have to be decreased. Rather, a masking layer 8 is applied to the smooth surface of the intermediate layer 2 facing away from the growth substrate 1. The masking layer is formed from SiN, for example, and includes openings 81 toward the intermediate layer 2.

Since the masking layer 8 is laterally overgrown by n-conducting GaN-based semiconductor material, for example, a structured layer 21 forms during the epitaxial deposition of corresponding semiconductor material. The structured layer 21 comprises the structured surface 3 at its side facing away from the growth substrate 1. The active layer 4 is subsequently grown onto the structured surface, as described above, which active layer can conformally follow the structurings of the structured surface 3. Finally, a covering layer 5, for example, composed of p-doped semiconductor material, is applied.

In this case, it proves to be particularly advantageous if the openings 81 are arranged randomly with regard to their size and/or their position in the masking layer 8. A particularly suitable roughening of the structured surface 3 can be achieved as a result.

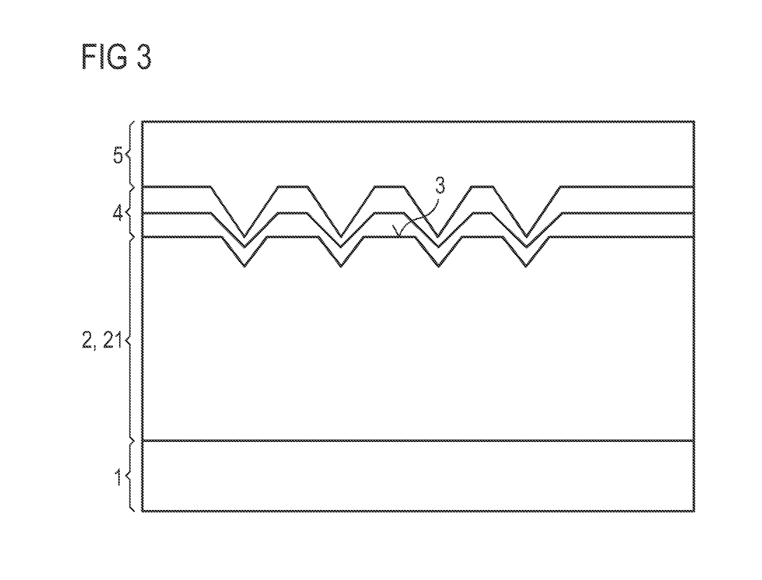

In conjunction with FIG. 3, a further exemplary embodiment of a method described here is explained in greater detail on the basis of a schematic sectional illustration showing an optoelectronic semiconductor chip produced by the method.

In contrast to the previous exemplary embodiments, in this exemplary embodiment the structured surface 3 forms at that side of the intermediate layer 2 itself which faces away from the growth substrate 1, such that the intermediate layer 2 is also the structured layer 21. This can be achieved at least in two ways.

Firstly, after the conclusion of the growth of the intermediate layer 2 and the decrease of the temperature in the epitaxy installation, the flow of the NH₃ precursor can be reduced or completely prevented. A decomposition of the GaN-based surface of the intermediate layer 2 and hence a roughening of said layer occur as a result of the reduced or absent nitrogen component. The active layer 4 is subsequently deposited conformally onto this structured surface 3, which active layer can be covered by the covering layer 5.

As an alternative possibility, the roughness can also be set by means of the rate of the carrier gas, for example, hydrogen in the epitaxy installation. If the rate of hydrogen is increased, then the roughness of the structured surface 3 increases. The same applies to increasing the temperature.

It is furthermore conceivable to prevent the flow of the NH₃ precursor at high temperatures, for instance at least 50 K, for example, 200 K, higher than the customary growth conditions for growing the active layer 4, for specific times. The desired roughening arises in this way, too.

All the methods described make it possible to increase the area of the active layer, that is to say the active outer area, from which electromagnetic radiation is emitted during operation, for example, by approximately a factor of 1.4. Increases in efficiency of up to 10% are possible in this way.

The invention is not restricted to the exemplary embodiments by the description on the basis of said exemplary embodiments. Rather, the invention encompasses any novel feature and also any combination of features, which particularly includes any combination of features in the patent claims, even if this feature or this combination itself is not explicitly specified in the patent claims or exemplary embodiments.

1-14. (canceled)

15. A method for producing an optoelectronic semiconductor chip, the method comprising:
providing a growth substrate in an epitaxy installation;
epitaxially depositing at least one intermediate layer over the growth substrate;
producing a structured surface facing away from the growth substrate at a side of the intermediate layer that faces away from the growth substrate; and
epitaxially depositing an active layer onto the structured surface;
wherein the structured surface is produced in the epitaxy installation; and
wherein the active layer follows the structuring of the structured surface conformally or substantially conformally at least in places.

16. The method according to claim 15, wherein the intermediate layer is based on GaN and, to form the structured surface, a flow of an NH₃ precursor is decreased or prevented for a specific time.

17. The method according to claim 16, wherein the flow of the NH₃ precursor is reduced or completely prevented after the conclusion of the growth of the intermediate layer, whereas on account of the reduced or absent nitrogen component, the GaN-based surface of the intermediate layer is partly decomposed, as a result of which the side of the intermediate layer that faces away from the growth substrate is roughened and forms the structured surface.

18. The method according to claim 17, wherein a temperature in the epitaxy installation is decreased before and during the reduction or prevention of the flow of the NH₃ precursor.

19. The method according to claim 18, wherein the temperature in the epitaxy installation is decreased below 900° C.

20. The method according to claim 15, wherein, to form the structured surface, the temperature in the epitaxy installation is reduced in such a way that V-defects form.

21. The method according to claim 20, wherein the intermediate layer comprises threading dislocations.

22. The method according to claim 21, wherein, for the most part, the V-defects respectively form at a threading dislocation.

23. The method according to claim 20, wherein the intermediate layer is based on GaN and the V-defects are grown at a temperature in the epitaxy installation of less than 900° C.

24. The method according to claim 15, wherein the intermediate layer consists of GaN and, to form the structured surface, a flow of an NH₃ precursor is decreased or prevented for a specific time.

25. The method according to claim 15, wherein a masking layer comprising a plurality of openings toward the intermediate layer is applied to the surface of the intermediate layer that faces away from the growth substrate, and wherein the structured surface is formed by epitaxial overgrowth of the masking layer.

26. The method according to claim 25, wherein the intermediate layer is exposed in the openings and the openings are partly filled during the epitaxial overgrowth.

27. The method according to claim 15, wherein the structured surface is produced by determined variation of growth conditions in the epitaxy installation.

28. The method according to claim 15, wherein the structured surface is produced by determined variation of a temperature in the epitaxy installation.

29. The method according to claim 15, wherein the structured surface is produced by determined variation of a flow rate of a precursor in the epitaxy installation.

30. The method according to claim 15, wherein the structured surface is produced by determined variation of a flow rate of a carrier gas in the epitaxy installation.

31. A method for producing an optoelectronic semiconductor chip, the method comprising:
providing a growth substrate in an epitaxy installation;
epitaxially depositing at least one intermediate layer over the growth substrate;
producing a structured surface facing away from the growth substrate at a side of the intermediate layer that faces away from the growth substrate;
epitaxially depositing an active layer onto the structured surface;
wherein the structured surface is produced in the epitaxy installation;
wherein the active layer follows the structuring of the structured surface conformally or substantially conformally at least in places;
wherein the intermediate layer is based on GaN and, to form the structured surface, a flow of an NH₃ precursor is decreased or prevented for a specific time;
wherein a masking layer comprising a plurality of openings toward the intermediate layer is applied to the surface of the intermediate layer that faces away from the growth substrate; and
the structured surface is formed by epitaxial overgrowth of the masking layer.
